(19) United States
(12) Patent Application Publication
(10) Pub. No.: US 2026/0173312 A1
(43) Pub. Date: Jun. 18, 2026

(54) HYBRID-COOLED LOAD BANK AND AI RACK EMULATOR

(71) Applicant: Deep Cool AI, Inc., Fremont, CA (US)

(72) Inventors: Davood Ghadiri Moghaddam, Fremont, CA (US); Kris Holla, Fremont, CA (US); Tikhon Suresh Pichai, Fremont, CA (US)

(73) Assignee: Deep Cool AI, Inc., Fremont, CA (US)

(21) Appl. No.: 19/353,354

(22) Filed: Oct. 8, 2025

Related U.S. Application Data
(60) Provisional application No. 63/705,799, filed on Oct. 10, 2024.

(51) Int. Cl. H05K 7/20

(52) U.S. Cl. CPC H05K 7/20272; H05K 7/20209; H05K 7/20263

(57) ABSTRACT

A hybrid-cooled load bank and AI rack emulator provides programmable emulation of both liquid-cooled and air-cooled heat rejection for data center and AI hardware commissioning. The hybrid-cooled load bank and AI rack emulator comprises a structural frame, heat generation assembly with liquid-cooled and air-cooled heat generation module, fluid management subsystem with a hydraulic impedance emulator, airflow management subsystem, power distribution subsystem, and control and monitoring subsystem. The method of emulating a hybrid-cooled AI rack includes establishing physical connections, initializing emulation parameters, configuring liquid and air paths, executing a dynamic emulation profile with real-time power commands and hybrid split allocation, and performing safe shutdown. The hybrid-cooled load bank and AI rack emulator enables programmable split control between cooling modes, dynamic response to bursty power profiles, and emulation of hydraulic impedance, addressing limitations of conventional load banks and supporting scalable, modular, and redundant operation for megawatt-class applications.

### CROSS REFERENCE TO RELATED APPLICATIONS

This utility patent application claims the priority of and benefit of provisional patent application 63/705,799, filed Oct. 10, 2024, which is incorporated by reference.

### BACKGROUND

Load banks have long been utilized for commissioning and performance validation of high-density IT infrastructure, particularly in data centers and environments deploying advanced computing hardware. Conventional load banks are typically designed to support either air-based or liquid-based cooling modes, but not both simultaneously. As a result, these load banks are unable to simulate combined cooling scenarios that are increasingly prevalent in modern data centers, where hybrid cooling strategies are employed to manage escalating thermal loads. The inability to replicate the interplay between air and liquid cooling in a controlled manner limits the effectiveness of commissioning processes and can result in incomplete validation of cooling system performance.

Traditional load banks are also limited in their ability to reproduce the complex, time-varying, and bursty power profiles that are characteristic of AI accelerator racks and other high-performance computing equipment. Existing systems generally provide static or slowly varying load profiles, which do not accurately reflect the rapid fluctuations in power demand observed in real-world AI workloads. This deficiency hampers the ability to assess the true operational behavior and resilience of power and cooling infrastructure under realistic conditions.

Another significant limitation of conventional load banks is the lack of programmable split control between liquid-cooled and air-cooled heat rejection. Existing solutions do not offer the capability to dynamically allocate heat rejection between liquid and air cooling paths over a full 0-100% range. This restricts the ability to test and validate the performance of hybrid cooling systems under varying operational scenarios, thereby reducing the fidelity of commissioning and validation processes.

Furthermore, current load banks do not provide a means to introduce controllable hydraulic impedance, which is necessary to emulate the pressure-drop versus flow characteristics of coolant distribution units. The absence of this capability prevents accurate simulation of the hydraulic behavior encountered in actual liquid cooling loops, leading to potential discrepancies between commissioning results and real-world operation.

Dynamic response is another area where existing load banks exhibit significant limitations. Conventional systems are generally unable to generate millisecond-class transients or support sub-Hertz modulation of load, both of which are essential for simulating the rapid power changes and low-frequency load variations typical of modern IT equipment. This lack of dynamic fidelity impedes comprehensive testing of both electrical and thermal management systems.

Finally, scalability and maintainability present ongoing challenges for load bank solutions. Traditional designs often struggle to scale to megawatt-class capacities while maintaining modularity, hot-swappability, and redundancy. The absence of modular, hot-swappable sub-assemblies complicates maintenance and expansion, and limits the ability to provide fault tolerance and continuous operation during commissioning activities. These limitations collectively hinder the deployment of robust, high-capacity load testing solutions suitable for next-generation data center environments.

### SUMMARY

The hybrid-cooled load bank and AI rack emulator, together with the associated method of emulating a hybrid-cooled AI rack, provides a comprehensive apparatus and process for simulating the thermal and electrical behavior of advanced data center equipment, particularly AI accelerator racks utilizing both liquid and air cooling. The hybrid-cooled load bank and AI rack emulator integrates a structural frame, a heat generation assembly comprising both liquid-cooled and air-cooled heat generation module, a fluid management subsystem, an airflow management subsystem, a power distribution subsystem, a control and monitoring subsystem, and a safety and service subsystem. The method of emulating a hybrid-cooled AI rack orchestrates the initialization, configuration, real-time control, and safe shutdown of the hybrid-cooled load bank and AI rack emulator, enabling precise emulation of complex, dynamic, and hybrid-cooled operational scenarios.

The hybrid-cooled load bank and AI rack emulator addresses the limitation of existing load banks that support only single-mode cooling by incorporating both a liquid-cooled heat generation module and an air-cooled heat generation module within the heat generation assembly. The liquid-cooled heat generation module includes an electric heater block, a liquid heat exchanger, an internal liquid loop, and module sensors, while the air-cooled heat generation module comprises a resistive heater element, variable-speed fans, an air duct housing, and module sensors. The fluid management subsystem, featuring a liquid manifold, quick-disconnect couplings, a hydraulic impedance emulator, and a recirculation sub-loop, enables simultaneous and independent operation of both cooling modes. This dual-mode capability allows the hybrid-cooled load bank and AI rack emulator to simulate combined cooling scenarios, which is not possible with prior art systems limited to either liquid or air cooling.

The method of emulating a hybrid-cooled AI rack overcomes the inability of conventional systems to reproduce time-varying, bursty power profiles characteristic of AI accelerator racks by implementing a dynamic emulation profile. The control and monitoring subsystem, including supervisory controller, touchscreen HMI, sensor array, and data logger, executes steps such as loading a dynamic power profile, generating real-time power commands, and allocating hybrid split in real time. The model-predictive control variant further enhances the system's ability to adapt to rapid changes in power demand, enabling the hybrid-cooled load bank and AI rack emulator to generate millisecond-class transients and sub-Hertz modulation, which are essential for accurately emulating the operational behavior of AI workloads.

The hybrid-cooled load bank and AI rack emulator introduces programmable split control between liquid-cooled and air-cooled heat rejection over a 0-100% range by utilizing the touchscreen HMI and supervisory controller to select and allocate the hybrid split. The method of emulating a hybrid-cooled AI rack includes steps for selecting the hybrid split, configuring the liquid and air paths, and allocating the hybrid split in real time based on the total power demand setpoint and real-time telemetry stream. This programmable split control enables precise emulation of a wide spectrum of hybrid cooling scenarios, providing a significant improvement over prior art systems that lack such flexibility.

The fluid management subsystem of the hybrid-cooled load bank and AI rack emulator incorporates a hydraulic impedance emulator, which includes an electronically controlled valve and a calibrated orifice set, to provide controllable hydraulic impedance. The method of emulating a hybrid-cooled AI rack includes steps for setting hydraulic impedance and validating liquid thermal conditions, allowing the system to emulate the pressure-drop versus flow behavior of coolant distribution units. This capability enables the hybrid-cooled load bank and AI rack emulator to accurately reproduce the hydraulic characteristics of real-world liquid cooling systems, which is not achievable with conventional load banks.

The hybrid-cooled load bank and AI rack emulator addresses limitations in dynamic response by integrating variable-speed fans, fast gating contactors, and a model-predictive control variant, enabling the system to generate rapid thermal and electrical transients. The method of emulating a hybrid-cooled AI rack includes steps for setting fan speeds, generating real-time power commands, and adapting the emulation profile to facility conditions, resulting in improved responsiveness and fidelity in simulating sub-second and sub-Hertz operational dynamics.

The hybrid-cooled load bank and AI rack emulator facilitate scaling to megawatt-class capacity through a modular architecture featuring hot-swappable module interface, redundant sub-assemblies, and a robust structural frame. The safety and service subsystem, including emergency stop, leak detection system, over-temperature/pressure protection, and hot-swappable module interface, ensures safe operation and maintainability. The method of emulating a hybrid-cooled AI rack supports modular expansion and redundancy by enabling the addition or replacement of modules without system downtime, providing a scalable and serviceable solution that surpasses the limitations of prior art systems.

A disclosed frame conforms to 19-inch rack standards (e.g., 48 U-60 U options) or a single integrated skid. Liquid modules include electric heaters thermally coupled to a liquid heat exchanger or a closed loop that rejects heat into the facility liquid via a plate heat exchanger. Air modules use resistive elements with ducted, variable-speed fans and optional acoustic treatment. A liquid manifold (supply/return) supports blind-mate or quick-disconnect couplings; optional by-pass and isolation valves simplify service. Pressure relief, drains, and air vents are provided. Modules are hot-swappable for serviceability and N+1 redundancy.

A disclosed liquid path provides adjustable hydraulic impedance via electronically controlled valves and optional calibrated orifices such that the presented pressure-drop-flow curve matches a target rack (e.g., 50-200 LPM at 1-3 bar AP). A recirculation sub-loop with a heat exchanger and pump can be included to decouple facility dynamics and to emulate thermal capacitance of device cold plates. Sensors include supply/return temperature, differential pressure, absolute pressure, flow, fluid conductivity, and optional glycol concentration.

A disclosed PDU/busbar delivers three-phase power (e.g., 415 V or 480 V) to sub-modules with branch protection and contactors for fast on/off gating. Electronic drive stages shape dynamic load profiles with slew-rate limits and current harmonics within code limits. The system supports ORV3-style busways or traditional PDUs.

A disclosed PLC/industrial controller executes user-defined profiles: step loads, ramps, burst pulses, PRBS, mHz-Hz sine sweeps, and workload-derived traces. Edge times down to the millisecond class are supported subject to electrical safety and grid codes. A supervisory algorithm enforces a target hybrid split by allocating power between liquid and air modules while maintaining hydraulic and airflow setpoints. Closed-loop control uses sensor feedback (power, temperatures, AP, flow) to match reference profiles and log results for CDU/FWS characterization.

Compared to single mode load banks of the prior art, a disclosed system overcomes prior art short falls as a disclosed system reproduces combined liquid-and-air heat rejection and hydraulic behavior in one apparatus; tracks millisecond-class dynamics; scales to megawatt class; and provides programmable split control and safety interlocks that reduce risk to expensive IT hardware during commissioning.

A disclosed method of operation includes a method of emulating an AI rack includes: (i) connecting supply/return liquid lines and electrical power; (ii) selecting a target hybrid split and dynamic power profile; (iii) commanding liquid module power and valve positions to achieve a desired AP-flow pair; (iv) commanding air module power and fan speeds to achieve a desired airflow and back-pressure; and (v) executing the profile while logging telemetry and enforcing safety limits. Variants include closed-loop tracking of measured facility conditions and adaptive profile correction.

In one embodiment, a hybrid load bank apparatus configured to emulate a rack of information technology equipment, comprising: (a) at least one liquid-cooled heat generation module fluidly coupled to a supply manifold and a return manifold; (b) at least one air-cooled heat generation module having a resistive heater and variable-speed fans; (c) power distribution circuitry to energize the modules; (d) sensors including at least liquid flow, liquid temperature, liquid differential pressure, air temperature, and electrical power; and (e) a controller programmed to apportion electrical power between the liquid-cooled and air-cooled modules according to a target hybrid split and to generate time-varying dynamic power profiles with specified slew-rates and frequency content.

The disclosed embodiments further overcome shortfalls in the art via, inter alia, in combining programmable liquid-and-air heat generation with hydraulic-impedance emulation and millisecond-class dynamic control in a scalable apparatus.

In summary, the hybrid-cooled load bank and AI rack emulator and the method of emulating a hybrid-cooled AI rack collectively provide a novel, flexible, and high-fidelity platform for emulating the complex thermal and electrical behavior of hybrid-cooled AI racks, addressing key technical challenges and delivering measurable improvements over existing load bank technologies.

### BRIEF DESCRIPTION OF FIGURES

FIG. 1A is a perspective of an embodiment comprising one liquid-cooled module.

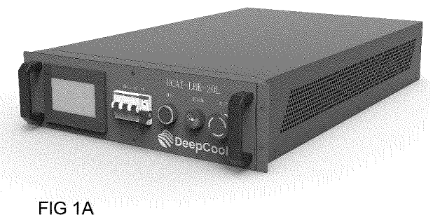

FIG. 1B is perspective view of an embodiment with one or more air-cooled modules within a single rack or frame.

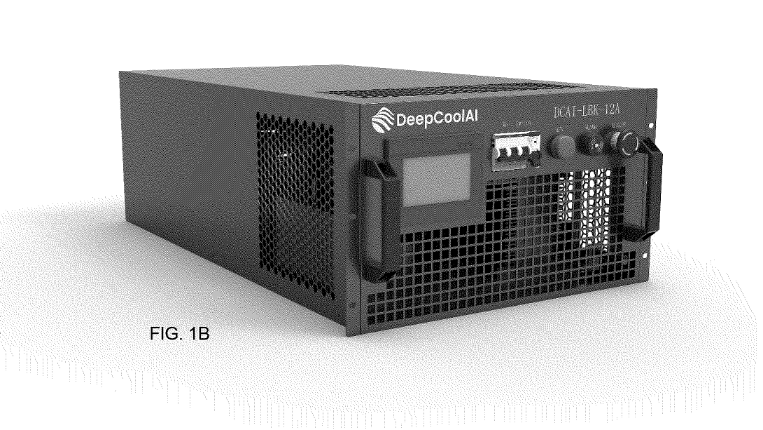

FIG. 2 is a perspective view of an embodiment with multiple rack-mount liquid-and air-cooled modules, PDUs, manifolds and controller in an IT rack.

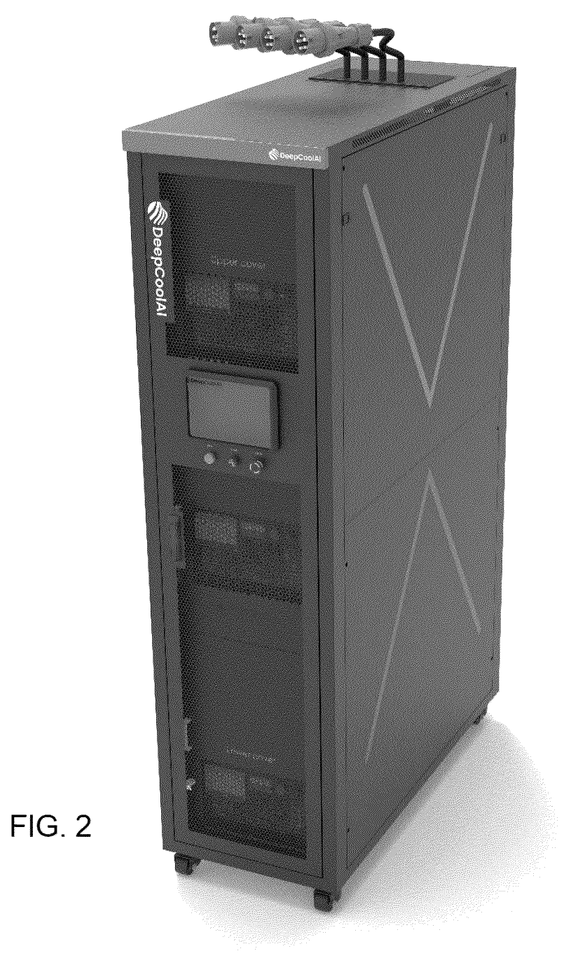

FIG. 3 is a schematic representation of one variant of the hybrid-cooled load bank and AI rack emulator.

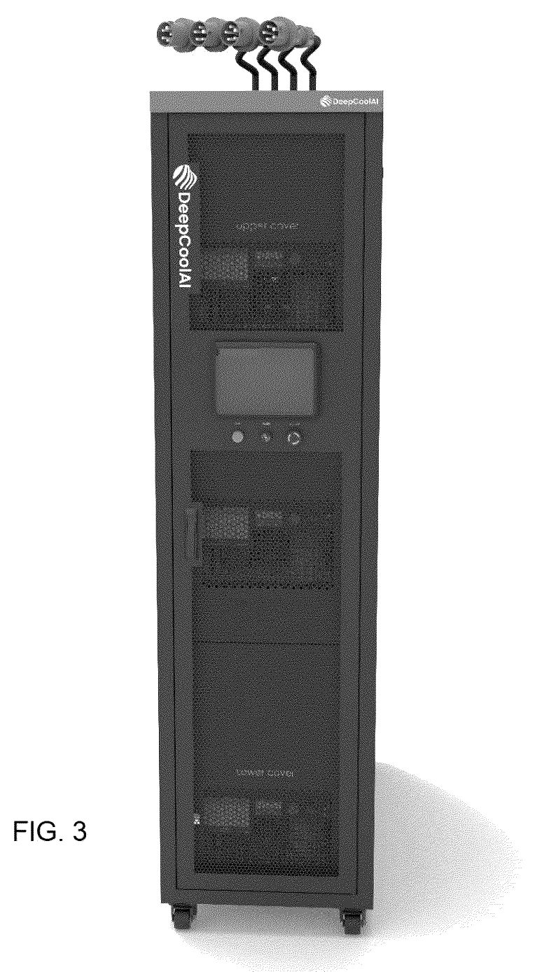

FIG. 4 is a perspective view of one variant of a disclosed embodiment.

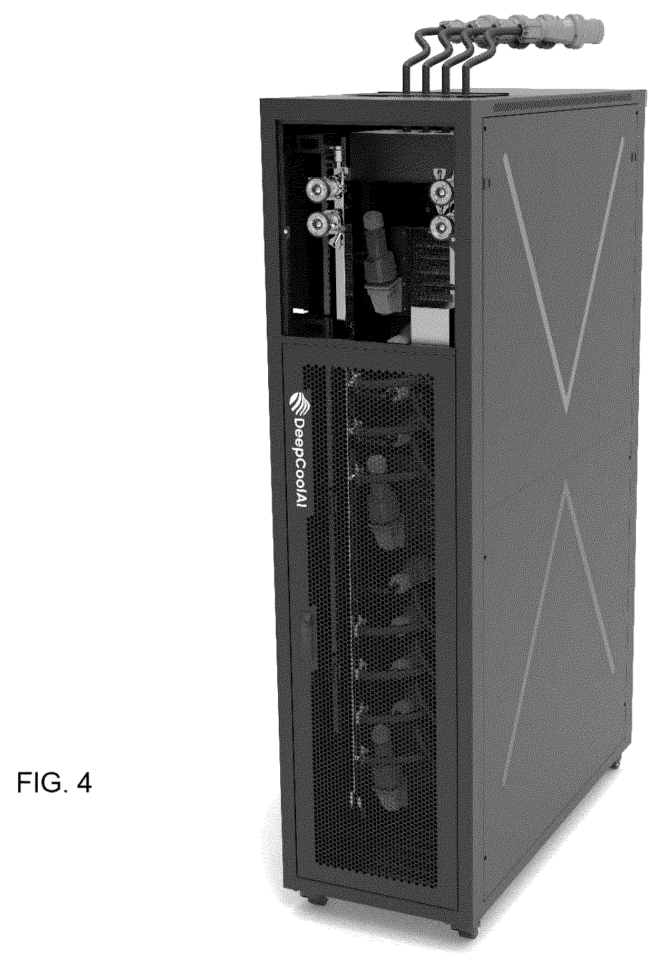

FIG. 5 is a perspective view of one variant of the hybrid-cooled load bank and AI rack emulator.

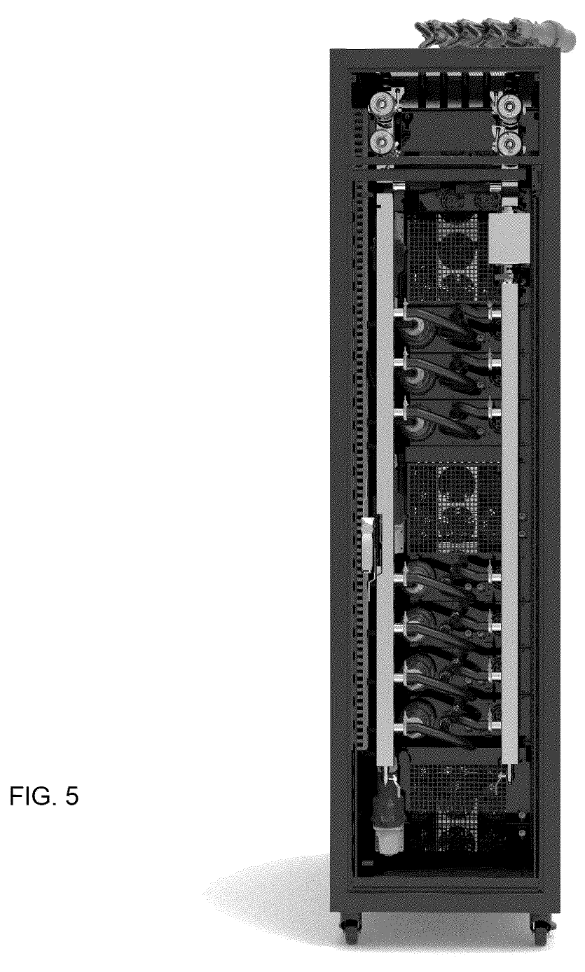

FIG. 6 is a perspective view of one variant of the hybrid-cooled load bank and AI rack emulator.

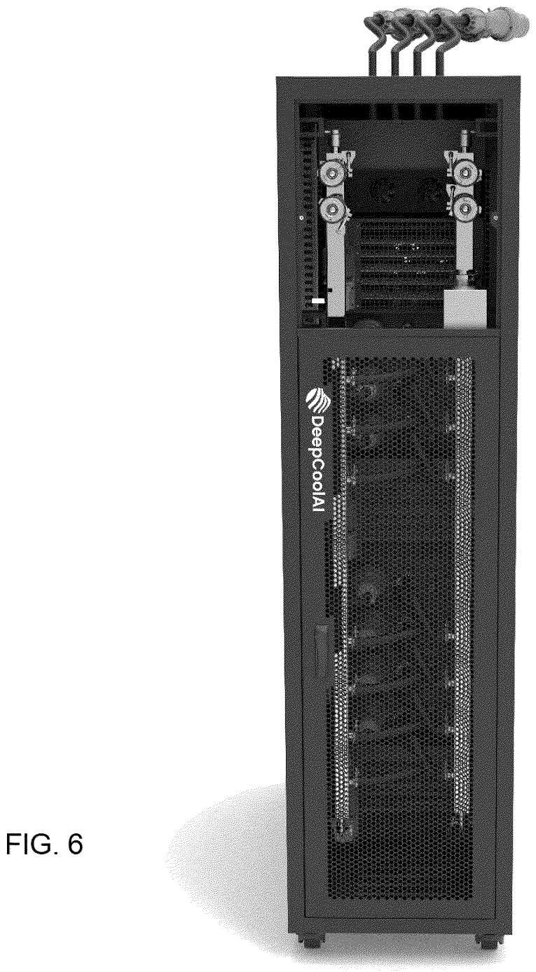

### DETAILED DESCRIPTION

The hybrid-cooled load bank and AI rack emulator can provide a modular, rack-mountable apparatus that emulates combined liquid-cooled and air-cooled thermal and hydraulic behavior of high-density information technology equipment racks within a structural frame conforming to standard 19-inch rack dimensions. The hybrid-cooled load bank and AI rack emulator can integrate three-phase power distribution with branch-level protection, embedded multi-domain sensors, and a supervisory controller that allocates electrical power between liquid-cooled and air-cooled modules according to a user-defined or algorithmically determined hybrid split adjustable from approximately 0% to 100% liquid heat rejection. The hybrid-cooled load bank and AI rack emulator can execute time-varying dynamic power profile that include steps, ramps, burst pulses, pseudo-random binary sequences, and frequency sweeps over approximately 0.001 Hz to 10 Hz with millisecond-class edge times to reproduce accelerator-rack transients. The hybrid-cooled load bank and AI rack emulator can present a programmable hydraulic impedance to an external coolant distribution unit by actuating electronically controlled valve and optional calibrated orifices to emulate target pressure-drop versus flow characteristics over exemplary ranges such as 50-200 LPM at 1-3 bar differential pressure. The hybrid-cooled load bank and AI rack emulator can support hot-swappable sub-assemblies with optional N+1 redundancy, integrated emergency stop and over-temperature/over-pressure protection, leak detection, and safe-state shedding to maintain serviceability and reliability during commissioning workflows. The hybrid-cooled load bank and AI rack emulator can scale from approximately 100 kW to at least 1 MW per frame and can parallel multiple frames under synchronized control to extend aggregate capacity for facility-level validation. Thus, the hybrid-cooled load bank and AI rack emulator addresses single-mode limitations, reproduces bursty AI power dynamics, provides programmable liquid/air split, emulates controllable hydraulic impedance, achieves rapid dynamic response, and scales capacity to enable commissioning and performance validation of hybrid-cooled AI racks in a single integrated platform.

### Heat Generation Assembly

A heat generation assembly can convert facility electrical power into thermal energy for simultaneous delivery to liquid and/or air media within a hybrid-cooled load bank. The heat generation assembly can include at least one liquid-cooled heat generation module and at least one air-cooled heat generation module, and the heat generation assembly can allocate electrical power between the modules according to a programmable hybrid split that varies from approximately 0% to 100% liquid heat rejection. The liquid-cooled heat generation module can couple an electric heater block to a liquid heat exchanger through an internal liquid loop so that the liquid-cooled heat generation module transfers heat into a circulating coolant to produce a heated coolant stream. The air-cooled heat generation module can position a resistive heater element within an air duct housing and can drive ducted flow using variable-speed fans so that the air-cooled heat generation module produces a heated airflow stream. The heat generation assembly can generate time-varying power profiles with millisecond-class slew rates and edge times, and the heat generation assembly can reproduce step changes, ramps, burst pulses, pseudo-random binary sequences, and frequency sweeps between approximately 0.001 Hz and 10 Hz. The heat generation assembly can interface with a hydraulic impedance emulator that includes an electronically controlled valve and a calibrated orifice set to present a specified pressure-drop versus flow characteristic to an external coolant distribution unit. The heat generation assembly can support hot-swappable sub-assemblies and N+1 redundancy so that the heat generation assembly scales from approximately 100 kW to at least 1 MW per rack or frame. module sensors can monitor electrical, thermal, and hydraulic parameters of the liquid-cooled heat generation module and the air-cooled heat generation module, and a supervisory controller can allocate power, enforce safety interlocks, and execute user-defined dynamic profiles for emulation of AI rack workloads. Therefore, the heat generation assembly enables combined-mode cooling with a continuously adjustable split, reproduces bursty AI power dynamics with fast transients, cooperates with hydraulic impedance emulation, and scales via modular redundancy to address the stated technical challenges.

### Liquid-Cooled Heat Generation Module

The liquid-cooled heat generation module can mount within the heat generation assembly as a rack-mountable cartridge that emulates liquid-cooled information technology equipment by coupling an electric heater block to a liquid heat exchanger and by rejecting heat into a facility coolant routed through supply and return manifolds. Generally, the liquid-cooled heat generation module can engage blind-mate and/or quick-disconnect couplings at the top panel with liquid couplings to support hot-swappable installation and N+1 redundancy without manual hose handling. More specifically, the liquid-cooled heat generation module can include an internal liquid loop that directs coolant across heat transfer surfaces while maintaining a controlled flow path compatible with the fluid management subsystem. Additionally, the liquid-cooled heat generation module can provide module sensors that measure supply and return temperature, absolute and differential pressure, and volumetric flow rate and that stream telemetry to the supervisory controller for closed-loop control. In one implementation, the liquid-cooled heat generation module can present a programmable hydraulic impedance by actuating an electronically controlled valve and/or by selecting a calibrated orifice set so that the module matches a target pressure-drop versus flow characteristic of a coolant distribution unit over a representative operating range (e.g., 10-300 kPa pressure drop at 5-120 L/min flow, as exemplary ranges). In another implementation, the liquid-cooled heat generation module can modulate power dynamically according to per-module power setpoints so that the module executes steps, ramps, pulses, and sub-Hertz to kilohertz-class frequency sweeps with edge times down to the millisecond range while maintaining safe junction temperatures. Further, the liquid-cooled heat generation module can incorporate leak detection and over-temperature/pressure protection that signal a safety override signal and that shed thermal load to place the module into a liquid-heater energised state or a safe-shutdown state, as commanded by the control and monitoring subsystem. In scalable deployments, the liquid-cooled heat generation module can deliver approximately 20-40 kW per cartridge and can aggregate multiple cartridges within a cabinet-level assembly to exceed 100-200 kW per frame, thereby enabling multi-module systems to scale toward 1 MW-class capacity. Therefore, the liquid-cooled heat generation module addresses the hybrid-cooling technical challenges by enabling liquid-side heat rejection with programmable hydraulic behavior, by supporting millisecond-class dynamic power modulation for AI rack emulation, and by scaling capacity with hot-swappable redundancy for large installations.

### Liquid Heat Exchanger

Generally, the liquid heat exchanger can couple thermally to the electric heater block of the liquid-cooled heat generation module and can transfer heat to a circulating coolant through a plate-based core that maximizes wetted surface area while maintaining a controlled pressure drop. More specifically, the liquid heat exchanger can employ a brazed or gasketed plate stack with internal turbulence-promoting features and flow channels sized to support exemplary flow rates between 10 and 200 LPM and exemplary differential pressures between 1 and 3 bar while distributing temperature uniformly across the plate area. In particular, the liquid heat exchanger can interface hydraulically to the liquid manifold via quick-disconnect couplings and/or blind-mate couplings so that the liquid-cooled heat generation module can achieve hot-swappable insertion and removal without draining the closed loop. Additionally, the liquid heat exchanger can incorporate integrated sensing of temperature, pressure, and flow so that the supervisory controller can compute closed-loop control actions and so that the data logger can capture telemetry for commissioning. Alternatively, the liquid heat exchanger can pair with the electronically controlled valve and/or the calibrated orifice set of the hydraulic impedance emulator so that the fluid management subsystem can present a programmable pressure-drop versus flow characteristic that emulates a target coolant distribution unit. Further, the liquid heat exchanger can utilize copper and/or stainless-steel wetted materials with corrosion-resistant finishes so that the liquid-cooled heat generation module can tolerate repeated thermal cycling and water-glycol coolant chemistries. Thus, the liquid heat exchanger addresses the absence of controllable hydraulic impedance and the lack of hybrid-capable, hot-swappable modules by enabling programmable flow-pressure behavior and rapid module-level integration within the hybrid-cooled load bank.

### Module Sensors

module sensors of the liquid-cooled heat generation module can include resistance temperature detectors and/or thermistors that position at a coolant inlet and a coolant outlet of the internal liquid loop to measure temperatures across the liquid heat exchanger, and module sensors of the liquid-cooled heat generation module can additionally position temperature sensors adjacent to an external airflow path to correlate liquid-side heat rejection with any concurrent air-side effects. More specifically, module sensors of the liquid-cooled heat generation module can mount differential-pressure transducers across a liquid supply and a liquid return manifold interface to determine an instantaneous pressure drop that characterizes hydraulic loading presented to the fluid management subsystem, and module sensors of the liquid-cooled heat generation module can install an in-line flow sensor, such as a turbine, ultrasonic, and/or electromagnetic type, to report a real-time volumetric flow rate (e.g., between 0.1 and 60 L/min with ±1-3% of reading accuracy). In particular, module sensors of the liquid-cooled heat generation module can acquire electrical parameters of the electric heater block (e.g., current and voltage for power calculation), thermal parameters of the heated coolant stream (e.g., inlet/outlet temperatures), and hydraulic parameters of the adjusted coolant flow (e.g., flow rate and differential pressure) and can transmit the measurements to the supervisory controller via an analog or digital interface, such as 4-20 mA, Modbus, and/or CAN bus at update rates suited to millisecond-class transients. Additionally, the supervisory controller can utilize the sensor data from module sensors of the liquid-cooled heat generation module to execute closed-loop control that generates per-module power setpoints, that enforces a target hybrid split command between liquid-cooled and air-cooled heat generation module, and that emulates a specified pressure-drop versus flow curve by coordinating the hydraulic impedance emulator according to the programmed hydraulic impedance configuration. Further, module sensors of the liquid-cooled heat generation module can furnish over-temperature, over-pressure, and leak detection signals to the over-temperature/pressure protection and the leak detection system to trigger a safety override signal that commands contactors and fast gating to shed load and to initiate a safe-shutdown state when thresholds are exceeded. Alternatively, module sensors of the liquid-cooled heat generation module can expand to include absolute pressure sensors, fluid conductivity probes, and glycol concentration sensors to characterize coolant quality, to detect entrained gas, and to validate mixture ratios for reliable heat transfer. In one implementation, module sensors of the liquid-cooled heat generation module can couple through the hot-swappable module interface using keyed connectors and non-volatile calibration storage to enable N+1 redundancy and field replacement without system recalibration, while the data logger can archive high-rate telemetry for later correlation. Thus, module sensors of the liquid-cooled heat generation module provide the measurement bandwidth and parameter coverage that the supervisory controller requires to apportion dynamic power profile across cooling modes, to maintain a programmable hybrid split over a 0-100% range, to coordinate controllable hydraulic impedance for accurate facility emulation, and to scale measurement and protection functions across hot-swappable modules for megawatt-class capacity.

### Air-Cooled Heat Generation Module

The air-cooled heat generation module can mount to a standard 19-inch rack in a 2 U-3 U form factor and can emulate residual air cooling of high-density AI equipment by driving a controlled heated airflow stream through a front-to-rear duct. The air-cooled heat generation module can include a resistive heater element positioned within an internal flow path to convert electrical input into heat with a power density selected to achieve per-module ratings in an exemplary range of 5-50 kW. The resistive heater element can segment into independently commanded banks to support sub-Hertz modulation and millisecond-class transients that match bursty accelerator workloads. The air-cooled heat generation module can include variable-speed fans that pull or push airflow across the resistive heater element and that adjust speed via pulse-width modulation and/or variable-frequency drive control to achieve target volumetric flow (e.g., 200-2,000 cubic feet per minute per module) and programmable backpressure. The variable-speed fans can coordinate with rack-level airflow conditions by receiving per-module power setpoints and fan-speed targets from the supervisory controller to maintain a commanded hybrid split. The air-cooled heat generation module can include an air duct housing that defines an internal plenum with perforated intake and exhaust panels to minimize flow bypass and to maintain uniform face velocity across the resistive heater element. The air duct housing can incorporate acoustic treatment panels and flow straighteners to reduce operational noise by an exemplary 3-10 dBA and to stabilize downstream pressure signals for more accurate control. The air-cooled heat generation module can include module sensors that measure inlet and outlet air temperatures, differential pressure across the air duct housing, fan tachometer signals, and delivered electrical power to enable closed-loop control and high-resolution telemetry logging. The module sensors can report data at rates in an exemplary range of 10-1,000 samples per second to support real-time power allocation and safety enforcement. The air-cooled heat generation module can present a hot-swappable electrical-mechanical interface with branch protection and local enable/disable controls on a front bezel to support N+1 redundancy and rapid replacement without disturbing adjacent modules. The air-cooled heat generation module can operate alone or alongside a liquid-cooled heat generation module while the supervisory controller allocates power between modules over a 0-100% range to achieve a commanded hybrid split and to reproduce rack-level thermal behavior. Therefore, the air-cooled heat generation module, together with the resistive heater element, the variable-speed fans, the air duct housing, and the module sensors, addresses combined-mode emulation, programmable airflow and back-pressure, millisecond-class dynamics, and modular scaling toward megawatt-class aggregate capacity.

### Module Sensors

The module sensors can instrument the air-cooled heat generation module with air temperature probes positioned at an inlet and an outlet of the air path and with airflow sensors configured to measure volumetric airflow through an air duct housing; more specifically, the module sensors can include resistance temperature detectors and/or thermistors for temperature sensing and hot-wire anemometers, differential pressure-based flow sensors, and/or vane-type flow meters for airflow measurement. The module sensors can interface electrically with an embedded controller of the air-cooled heat generation module and/or with a supervisory controller to provide real-time feedback that enables closed-loop regulation of a resistive heater element, variable-speed fans, and per-module power allocation. In one embodiment, the module sensors can further measure liquid temperature, differential pressure, and flow rate of a liquid-cooled path that shares a frame with the air-cooled heat generation module to support coordination of hybrid heat rejection. Additionally, the module sensors can monitor electrical current and voltage of heater circuits to quantify instantaneous power consumption and to detect abnormal operating conditions. In particular, the module sensors can sample all channels at rates suitable for millisecond-class transients (e.g., between 1 kHz and 5 kHz) while the embedded controller can filter and down-sample data to support sub-Hertz modulation analysis. The module sensors can present hot-swap connectors and in-situ calibration routines to allow replacement and verification without requiring shutdown of the air-cooled heat generation module, and the module sensors can support N+1 redundancy at a probe level to maintain validity of telemetry during maintenance events. The module sensors can publish timestamped measurements to a data logger to enable reconstruction of inlet-to-outlet temperature rise, mass-flow-derived heat transfer, and control-loop performance under bursty load profiles. Thus, the module sensors enable accurate real-time airflow and temperature feedback for closed-loop control, enable fast transient tracking for AI-like bursts, enable enforcement of safety limits for over-temperature and abnormal flow, and enable coordinated hybrid split regulation, thereby addressing limitations in dynamic response, split programmability, and scalable, hot-swappable operation in conventional load banks.

### Fluid Management Subsystem

The fluid management subsystem can route facility coolant supply through a plumbing network that the fluid management subsystem configures to feed and return flow for the heat generation assembly while preserving hybrid operation with the airflow management subsystem. Generally, the liquid manifold can distribute and collect coolant across parallel branches that the liquid manifold sizes and spaces to minimize dead volume and to support hot-swappable module interface alignment without imposing excessive header velocity. More specifically, the quick-disconnect couplings can mate to external coolant distribution units and/or facility water systems, and the quick-disconnect couplings can engage integral check features and dripless seals to enable rapid connection and disconnection during establish physical connections. In particular, the hydraulic impedance emulator can present a programmable pressure-drop versus flow characteristic that the hydraulic impedance emulator maps to a target IT rack or cold plate assembly profile. Additionally, the electronically controlled valve can modulate opening area over a commanded range (e.g., 0-100%) to vary dynamic resistance in real time, and the electronically controlled valve can coordinate with the supervisory controller to reproduce sub-Hertz modulation and millisecond-class transients. Alternatively, or additionally, the calibrated orifice set can insert or bypass fixed elements of known K-factors so that the calibrated orifice set establishes repeatable baseline impedance states for programmed hydraulic impedance configuration. Further, the recirculation sub-loop can decouple facility-side flow from module-side demand by circulating coolant through an internal path that the recirculation sub-loop thermally conditions before returning to the liquid manifold. In one implementation, the pump can drive controllable flow within the recirculation sub-loop to emulate device-side inertia, the secondary heat exchanger can absorb or reject heat to shape thermal mass, and the buffer reservoir can accommodate volume change and air separation to stabilize transient behavior. Also, the pressure relief and drain assembly can provide over-pressure protection, venting, and service drainage that the pressure relief and drain assembly coordinates with leak detection system features described elsewhere to support safe maintenance. Moreover, the sensor array can measure supply and return temperatures, differential and absolute pressures, flow rates, conductivity, and optional glycol concentration, and the sensor array can stream real-time telemetry to the supervisory controller for closed-loop control and enforce safety limits. Thus, the fluid management subsystem addresses absent controllable hydraulic impedance by enabling programmable pressure-flow behavior, improves dynamic response by using the recirculation sub-loop to shape transient thermal and hydraulic dynamics, and supports scalable, hot-swappable capacity and safe commissioning through the liquid manifold, quick-disconnect couplings, and pressure relief and drain assembly without constraining subsequent subsection details.

### Liquid Manifold

The liquid manifold can route coolant through a pair of supply and return headers that extend vertically along the height of the structural frame to distribute and collect flow for each liquid-cooled heat generation module. More specifically, the liquid manifold can present blind-mate and/or quick-disconnect stubs at each hot-swappable module interface position to enable tool-less connection and disconnection of a module without manual hose handling or depressurization. In one implementation, the liquid manifold can include corrosion-resistant piping with cross-sectional geometry dimensioned to support an aggregate flow rate in an exemplary range of 50-200 liters per minute at an exemplary pressure differential of 1-3 bar that aligns with coolant distribution unit and facility water system specifications. Additionally, the liquid manifold can provide integrated sensor ports positioned along the supply header and the return header to measure temperature, absolute pressure, differential pressure, and flow rate at rack level and at individual module positions for closed-loop control by the supervisory controller. In one embodiment, the liquid manifold can incorporate bypass and isolation valves to facilitate service of a single module and/or a subset of modules while the fluid management subsystem remains active. Further, the liquid manifold can integrate a pressure relief and drain assembly and an air vent feature to support safe purge, fill, and maintenance operations of the internal liquid loop and the recirculation sub-loop. In one implementation, the liquid manifold can cooperate with the hydraulic impedance emulator by directing flow through an electronically controlled valve and/or a calibrated orifice set to emulate a programmable pressure-drop versus flow characteristic that represents a target coolant distribution unit. Additionally, or alternatively, the liquid manifold can coordinate with the quick-disconnect couplings on the top panel with liquid couplings to allocate flow to selected modules and to support a programmable split of heat rejection between liquid and air paths over a 0-100% range. In another implementation, the liquid manifold can support rapid scaling by accepting additional parallel headers and additional module stubs to extend capacity toward megawatt-class operation with N+1 redundancy across modules and pump. Thus, the liquid manifold addresses combined cooling simulation, programmable split control, controllable hydraulic impedance emulation, and scalable capacity challenges by furnishing instrumented, serviceable distribution that enables dynamic, module-level flow control and fast reconfiguration.

### Hydraulic Impedance Emulator

Generally, the hydraulic impedance emulator can present a programmable hydraulic load by shaping a pressure-drop versus flow characteristic to an external coolant distribution unit and/or a facility water system so that the fluid management subsystem can emulate a target cold-plate assembly over exemplary ranges of 50-200 LPM and 1-3 bar AP. The supervisory controller can command the hydraulic impedance emulator to achieve a specified differential pressure at a target flow by selecting an orifice configuration and by issuing valve-position setpoints according to an emulation parameter set and a hydraulic and airflow target set. The electronically controlled valve can provide continuously variable throttling with a proportional control action and a response bandwidth that can support millisecond-class transients and sub-Hertz modulation so that the hydraulic impedance emulator can reproduce time-varying or bursty flow conditions. The calibrated orifice set can provide discrete impedance steps via interchangeable and uniquely sized inserts so that the hydraulic impedance emulator can establish a predictable baseline resistance and extend the effective control range while maintaining low valve authority where appropriate. The hydraulic impedance emulator can include integrated sensors for supply pressure, return pressure, volumetric flow rate, and fluid temperature so that the supervisory controller can execute closed-loop control and validate adjusted coolant flow against the programmed hydraulic impedance configuration. The model-predictive control variant can anticipate facility-side disturbances and adjust commands to the hydraulic impedance emulator to maintain the requested AP-Q trajectory while minimizing overshoot and valve travel. The hydraulic impedance emulator can implement a modular and hot-swappable assembly with an N+1 arrangement so that the safety and service subsystem can support rapid replacement and maintain operation during service events. Thus, the hydraulic impedance emulator and the electronically controlled valve and the calibrated orifice set can address the absence of controllable hydraulic impedance and the limitations in dynamic response by enabling precise, repeatable, and rapidly adjustable pressure-flow behavior that facilitates commissioning and performance validation of coolant distribution infrastructure.

### Power Distribution Subsystem

The power distribution subsystem can comprise a three-phase PDU/busbar network configured to deliver facility electrical power to the liquid-cooled heat generation module and the air-cooled heat generation module, with exemplary frame ratings scalable from approximately 100 kW up to at least 1 MW per structural frame and with compatibility for three-phase supply voltages (e.g., 415 V or 480 V). More specifically, the PDU/busbar can route phase-balanced feeders to hot-swappable module interface positions and can implement ORV3-style busways and/or traditional rack-mount PDUs and/or custom busbar assemblies to accommodate varying ampacity and connection geometry. Additionally, the branch protection devices can provide per-module overcurrent interruption via miniature circuit breakers and/or electronic protection devices to isolate faults and to enable selective service without de-energizing unaffected modules. In particular, the contactors and fast gating can switch branch circuits with millisecond-class on/off transitions via electromechanical contactors and/or solid-state switches to generate steps, ramps, pulses, and frequency sweeps with commanded edge times in an exemplary 1-10 ms range. Furthermore, the power distribution subsystem can interface with the supervisory controller to accept per-module power setpoints, to enforce slew-rate limits, and to maintain current harmonics within applicable electrical code limits while the integrated metering of the power distribution subsystem reports branch-level and system-level voltage, current, and power for closed-loop power management and safety enforcement. In one embodiment, the power distribution subsystem can support N+1 redundancy and hot-swappable module replacement so that the hybrid-cooled load bank and AI rack emulator can sustain operation during maintenance or a protection event. Therefore, the power distribution subsystem enables megawatt-class scalability, millisecond dynamic response, and uninterrupted modular serviceability, which addresses limitations in conventional load banks regarding capacity scaling, reproduction of time-varying AI power profiles, and maintenance without test interruption.

### Sensor Array

Generally, the sensor array can comprise a distributed network of electrical, thermal, and hydraulic sensors that sample and transmit real-time measurements to the control and monitoring subsystem. More specifically, the sensor array can measure electrical power parameters including voltage (e.g., line-to-line and line-to-neutral across a range of 120-600 V), current (e.g., 0 -2,000 A per phase), and power factor (e.g., 0.5-1.0 lagging/leading) to characterize consumption of the heat generation assembly. In particular, the sensor array can capture liquid and air temperatures at supply, return, and internal module locations with contact probes and RTD/thermistor elements that cover exemplary ranges of −10 to 100° C. for air and 0 to 60° C. for coolant. Additionally, the sensor array can monitor liquid flow rates (e.g., 0.1-6.0 L/s per branch), differential and absolute pressures in the liquid circuit (e.g., 0-700 kPa absolute and 0-200 kPa differential), airflow rates through the airflow management subsystem (e.g., 0.1-10 m³/s), and ambient conditions such as room temperature, humidity, and barometric pressure. The sensor array can interface with the supervisory controller via the control-network interface and can provide continuous feedback that enables closed-loop control of power allocation, hybrid split, and dynamic power profile execution across the liquid-cooled heat generation module and the air-cooled heat generation module. The sensor array can furnish timestamped samples to the data logger at user-selectable sampling rates (e.g., 100 Hz-5 kHz) to capture millisecond-class transients and to support analysis of sub-Hertz modulation during execute dynamic emulation profile. In one implementation, the sensor array can include additional sensing for fluid conductivity (e.g., 0.1-10 mS/cm), leak detection along the fluid management subsystem, and glycol concentration estimation (e.g., via refractometry or thermal conductivity) to enhance operational safety and emulate facility coolant chemistry. In another implementation, the sensor array can position sensors at manifold inlets and outlets, at module supply and return lines, within each hot-swappable module interface, and at strategic points of the air duct and plenum to resolve spatial gradients and to support per-module power setpoints. The sensor array can support modular expansion and redundancy by allowing daisy-chained or star-wired additions of sensing nodes so that the control and monitoring subsystem can scale across racks rated from an exemplary 100 kW to 1 MW or higher while maintaining deterministic sampling and synchronization. The sensor array can meet applicable industrial and IT equipment standards by implementing accuracy classes (e.g., ±0.5-1.0% of reading), response times (e.g., 5-20 ms step response), and reinforced electrical isolation (e.g., 1-3 kV) on measurement channels to maintain measurement integrity under high dV/dt switching of contactors and fast gating. Thus, the sensor array addresses the field challenges by enabling closed-loop hybrid cooling control with programmable split, by capturing time-varying bursty profiles with millisecond response, by informing hydraulic impedance emulation through accurate pressure/flow telemetry, and by supporting megawatt-class scaling with redundant, modular sensing.

### Method of Emulating a Hybrid-Cooled AI Rack

The supervisory controller can execute the method of emulating a hybrid-cooled AI rack by orchestrating a sequence that establishes utility connections, initializes targets, configures thermal paths, drives dynamic loading, and returns the hybrid-cooled load bank and AI rack emulator to a safe-shutdown state; more specifically, the quick-disconnect couplings can connect liquid lines to a facility coolant supply and a return to form a liquid circuit connected configuration, the PDU/busbar can connect electrical power to achieve an electrical power connected configuration, and the supervisory controller can connect control communications to establish a control communications link established configuration. The touchscreen HMI can select hybrid split to produce a hybrid split command over a 0-100% liquid heat rejection range, the supervisory controller can load dynamic power profile data to produce a dynamic power profile with features between approximately 0.001 Hz and 10 Hz and edge times down to the millisecond range, and the supervisory controller can define hydraulic and airflow targets to produce a hydraulic and airflow target set that forms an emulation parameter set. The supervisory controller can configure liquid path by commanding the liquid-cooled heat generation module to energize liquid-cooled modules until a liquid-heater energized state produces a heated coolant stream, the electronically controlled valve and the calibrated orifice set can set hydraulic impedance to produce an adjusted coolant flow that emulates a pressure-drop versus flow characteristic (e.g., approximately 50-200 LPM at approximately 1-3 bar AP), and the supervisory controller can validate liquid thermal conditions using the heated coolant stream and the adjusted coolant flow to achieve a liquid path configured configuration. The supervisory controller can configure air path by commanding the air-cooled heat generation module to energize air-cooled modules until a heated airflow stream forms, the variable-speed fans can set fan speeds to achieve airflow consistent with the hydraulic and airflow target set, and the supervisory controller can validate air thermal conditions to achieve an air path configured configuration. The supervisory controller can execute dynamic emulation profile by generating real-time power commands that yield a total power demand setpoint, allocating hybrid split in real time to produce per-module power setpoints that divide power between the liquid-cooled heat generation module and the air-cooled heat generation module according to the updated hybrid split target, and adapting profile to facility conditions using a real-time telemetry stream and the emulation parameter set to produce an emulation profile adjustment that maintains emulation accuracy under varying supply temperature, flow, or pressure. The data logger can monitor and log telemetry using the total power demand setpoint and the per-module power setpoints to produce a real-time telemetry stream and a commissioning telemetry dataset, and the over-temperature/pressure protection can enforce safety limits using the real-time telemetry stream to produce a safety override signal that constrains the supervisory controller during the execute dynamic emulation profile step. The supervisory controller can terminate and safe shutdown by ramping down thermal load to achieve a ramped-down thermal state, commanding cool-down and isolate to yield a cooled and isolated state while the fluid management subsystem and the airflow management subsystem remove residual heat, and archiving data and report results to produce a commissioning report and an archived telemetry package; additionally, the emergency stop and the leak detection system can trigger an early return to a safe-shutdown state when the over-temperature/pressure protection signals a safety override signal. The hot-swappable module interface can support modular, N+1 redundant operation across an exemplary 100 kW to at least 1 MW total load range by allowing the heat generation assembly and the power distribution subsystem to add or remove sub-assemblies without disturbing the utilities-connected load-bank state; therefore, the supervisory controller and the associated subsystems address combined liquid-and-air cooling emulation, programmable 0-100% split control, controllable hydraulic impedance, millisecond-class transient reproduction, and scalable capacity such that commissioning of high-density IT infrastructure proceeds under realistic and repeatable AI rack conditions.

### Initialize Emulation Parameters

The supervisory controller can initialize emulation parameters by receiving, via the touchscreen HMI and/or a control-network interface, operator-defined configuration data that the supervisory controller associates with an emulation parameter set. More specifically, the touchscreen HMI can select hybrid split by capturing a percentage allocation of total heat rejection between the liquid-cooled path and the air-cooled path over a continuous range (e.g., approximately 0% to approximately 100%), and the touchscreen HMI can transmit a hybrid split command to the supervisory controller for inclusion in the emulation parameter set. In addition, the supervisory controller can load a dynamic power profile by accepting predefined or user-uploaded sequences such as step changes, linear or nonlinear ramps, pseudo-random binary sequences, sine sweeps, and burst pulses with frequency content (e.g., approximately 0.001 Hz to approximately 10 Hz) and edge times in the millisecond class, and the supervisory controller can store the dynamic power profile as part of the emulation parameter set. Further, the supervisory controller can define hydraulic and airflow targets by receiving target pressure-drop versus flow characteristics for the liquid path and target volumetric flow and back-pressure for the air path, and the supervisory controller can package a hydraulic and airflow target set within the emulation parameter set. Then, the supervisory controller can validate all input parameters against pre-programmed safety limits for maximum allowable power, temperature, pressure, and flow, and the supervisory controller can reject or modify entries that would exceed safe operating conditions. Subsequently, the supervisory controller can compute initial per-module power setpoints for the heat generation assembly and can compute initial setpoints for the electronically controlled valve and the variable-speed fans to satisfy the hybrid split command under the loaded dynamic power profile. In one implementation, the supervisory controller can pre-calculate expected system responses from the emulation parameter set to enable predictive safety checks and to log baseline conditions prior to execution. Therefore, the supervisory controller and the touchscreen HMI can provide precise and repeatable configuration that enables combined liquid and air emulation with a programmable 0-100% split, that accommodates time-varying bursty profiles with millisecond edges, and that establishes hydraulic-impedance and airflow objectives to address limitations of single-mode load banks and slow-response emulators.

### Select Hybrid Split

A user may use the touchscreen HMI to select hybrid split as a continuous target between approximately 0% and 100% of liquid-cooled heat rejection, and the touchscreen HMI can transmit the selection as a hybrid split command to the supervisory controller for inclusion in an emulation parameter set; alternatively, the supervisory controller can compute the target hybrid split from a predefined dynamic power profile and/or from measured coolant supply temperature, flow rate, and pressure reported by the sensor array. The supervisory controller can apportion initial per-module power setpoints across the liquid-cooled heat generation module and the air-cooled heat generation module according to the hybrid split command while maintaining a total power demand setpoint defined during initialized emulation parameters, and the supervisory controller can store the hybrid split command for later modification during allocate hybrid split in real time. Additionally, the supervisory controller can schedule stepwise or continuous modulation of the hybrid split over a time horizon to emulate transient or steady-state distributions, and the supervisory controller can sweep the hybrid split through a range (e.g., 0-100% liquid in exemplary increments or waveforms) to characterize external cooling infrastructure response under varying load allocations. In one implementation, the control and monitoring subsystem can adjust the hybrid split adaptively by applying updated hybrid split target values derived from an emulation profile adjustment and a safety override signal so that the control and monitoring subsystem preserves thermal and electrical limits while reproducing mixed-cooling scenarios typical of AI accelerator racks. Thus, the touchscreen HMI and the supervisory controller together enable programmable, dynamic selection of liquid-versus-air heat rejection, which addresses the lack of combined-mode support and the absence of fine split control in conventional load banks while supporting rapid transitions needed to emulate bursty AI workloads.

### Load Dynamic Power Profile

Generally, the supervisory controller can load a dynamic power profile by selecting or receiving a time-varying command signal that specifies electrical power versus time for the hybrid-cooled load bank and AI rack emulator. More specifically, the supervisory controller can choose a pre-stored waveform from a library of standard profiles-such as step changes, ramps, burst pulses, pseudo-random binary sequences, and frequency sweeps-or the supervisory controller can ingest a user-defined trace that encodes magnitude as a function of time. In particular, the dynamic power profile can define frequency content over an exemplary range of approximately 0.001 Hz to 10 Hz with programmable edge times down to an exemplary range of 1 ms to 20 ms to enable rapid transients and sub-Hertz modulation. Additionally, the dynamic power profile can specify magnitude as absolute power, as a percentage of rated capacity, and/or as a normalized trace, and the dynamic power profile can include parameters for slew-rate limits, dwell durations, and repetition cycles. Further, the supervisory controller can validate the selected or uploaded dynamic power profile against safety constraints provided by the power distribution subsystem and the safety and service subsystem, including bounds on maximum allowable current, voltage, and thermal rise rates. In one implementation, the touchscreen HMI can provide graphical tools for waveform editing, preview, and scheduling to streamline preparation of the dynamic power profile. Alternatively, the supervisory controller can apply the dynamic power profile globally to the heat generation assembly or the supervisory controller can apportion the dynamic power profile between the liquid-cooled heat generation module and the air-cooled heat generation module according to a hybrid split command. Then, the supervisory controller can parameterize per-module interpretation so that the dynamic power profile maps to per-module power setpoints with programmable scaling and timing alignment. In one embodiment, the supervisory controller can adjust the loaded dynamic power profile in real time based on a real-time telemetry stream that indicates facility coolant supply temperature, flow, and pressure to maintain emulation accuracy under varying external conditions. Therefore, the supervisory controller and the dynamic power profile together address time-varying and bursty workload emulation with millisecond-class edges and sub-Hertz content while enabling programmable split control across liquid-cooled and air-cooled paths without violating electrical or thermal safety constraints.

### Define Hydraulic and Airflow Targets

Generally, the supervisory controller can define hydraulic and airflow targets by generating a hydraulic and airflow target set that specifies liquid-path pressure-drop versus flow-rate profiles and air-path volumetric-flow versus static-pressure curves that emulate a high-density AI rack. More specifically, the touchscreen HMI can accept user input that selects a pre-defined profile or that enters custom set-points for a liquid-path ΔP-Q curve, such as a pressure-drop in an exemplary range of 1-3 bar at a flow rate between an exemplary 50-200 L min⁻¹, while the supervisory controller can parameterize interpolation across multiple breakpoints to cover an exemplary 0.1-0.5 bar residual margin outside the nominal operating region. In particular, the supervisory controller can also define airflow targets by specifying an exemplary volumetric-flow range (e.g., 1,000-10,000 m³·h⁻¹) versus an exemplary static-pressure range (e.g., 50-300 Pa) so that the airflow management subsystem can later reproduce back-pressure characteristics of rack baffles and perforated tiles. Additionally, the supervisory controller can incorporate dynamic targets by scheduling ramps, steps, and sub-Hertz modulations of flow and pressure over an exemplary 1-300 s interval and by specifying millisecond-class setpoint updates for transient events so that subsequent control loops can track bursty demands. Alternatively, the supervisory controller can select a profile template that corresponds to a coolant distribution unit or an air mover standard and can annotate the template with tolerance bands for allowable deviation (e.g., ±5-10%) to guide validation. Then, the supervisory controller can package the selected and/or custom parameters as the hydraulic and airflow target set and can publish the hydraulic and airflow target set to the control and monitoring subsystem for later use by the electronically controlled valve and the variable-speed fans during configuration and validation. Thus, the supervisory controller addresses the technical challenges by enabling combined liquid and air target definition with programmable impedance characteristics and time-varying behaviors, which prepares the apparatus to reproduce hybrid cooling conditions and dynamic responses encountered in AI accelerator racks.

### Establish Physical Connections

Generally, the supervisory controller can execute establish physical connections by coordinating physical coupling of utilities and by withholding load enablement until validation succeeds. More specifically, the quick-disconnect couplings can mate a facility coolant supply and a facility coolant return to the liquid manifold via the top panel with liquid couplings to provide a tool-less, leak-resistant interface suitable for rapid deployment. Additionally, the PDU/busbar can connect facility electrical power, such as three-phase 415-480 V in an exemplary range, while the branch protection devices and the contactors and fast gating can provide per-branch isolation and controlled energization. In particular, the supervisory controller can establish control communications to a control-network interface via Ethernet and/or fieldbus and/or proprietary serial links to enable remote monitoring and command. Further, the sensor array can verify correct engagement of liquid and electrical couplings by measuring proximity-switch states, differential and static pressure signals, and electrical continuity, and the data logger can record connection status and timestamps for traceability. Then, the supervisory controller can inhibit load application by holding the contactors and fast gating open until the sensor array reports all parameters within specified thresholds and can generate alarms and lockouts if improper or incomplete connections are detected. Additionally or alternatively, the safety and service subsystem can connect auxiliary lines, and the leak detection system can provide wiring continuity and wetness signals that the supervisory controller evaluates as part of connection readiness. Thus, the supervisory controller can assert a verified facility connection configuration to enable subsequent configuration of liquid and air paths while addressing safe, reliable integration that precedes hybrid cooling and high-dynamic emulation steps.

### Connect Liquid Lines

As part of establish physical connections, quick-disconnect couplings can execute connect liquid lines by aligning with the facility coolant supply and by engaging with the top panel with liquid couplings to complete a supply and return interface to the liquid manifold. Generally, an operator can align quick-disconnect couplings with color-coded supply and return ports of the top panel with liquid couplings and can mate the couplings in a blind-mate motion that the quick-disconnect couplings guide to prevent cross-connection. More specifically, quick-disconnect couplings can engage mechanical latching and/or locking features to create a leak-free hydraulic seal to the liquid manifold and to resist accidental disconnection during operation. Subsequently, the supervisory controller can initiate a verification sequence and can command the sensor array to measure conductivity across a liquid path defined by the liquid manifold and the recirculation sub-loop to confirm coolant presence and absence of air gaps. In particular, the leak detection system can monitor interfaces at the quick-disconnect couplings and an area of the pressure relief and drain assembly to detect any fluid escape before the method of emulating a hybrid-cooled AI rack proceeds. Additionally or alternatively, the recirculation sub-loop can purge air by driving the pump to circulate coolant through the buffer reservoir and by venting through the pressure relief and drain assembly, and an operator can perform a manual purge using service fittings of the pressure relief and drain assembly. In one implementation, the data logger can record a connection event and can capture baseline pressure and flow values that the sensor array reports while the supervisory controller can validate correct flow direction through the liquid manifold relative to intended supply and return mapping. In another implementation, the safety and service subsystem can permit a powered-on or powered-off connection based on hot-swap capability of the quick-disconnect couplings and based on interlock logic of the over-temperature/pressure protection that the supervisory controller enforces. Thus, connect liquid lines can establish a reliable fluid interface that enables configuration of the hydraulic impedance emulator and liquid-cooled heat generation module, which addresses combined-cooling emulation and controllable hydraulic impedance challenges by preparing the system for accurate hybrid load and time-varying thermal profile execution.

### Connect Electrical Power

The PDU/busbar can connect electrical power by engaging facility electrical power at rack-level feeds and by routing three-phase conductors and a protective earth into the power distribution subsystem. More specifically, the branch protection devices can close miniature circuit breakers to establish per-sub-module isolation and overcurrent protection, and the contactors and fast gating can energize selected branches to enter an electrical power connected configuration while maintaining controlled inrush and fast de-energization capability. Additionally, an operator may perform a ground-bond continuity check using integrated test points or external test equipment to verify that exposed conductive parts of the hybrid-cooled load bank and AI rack emulator are earthed according to applicable electrical safety standards, and the operator may verify integrity of a main protective earth conductor and confirm that leakage current paths remain within specified limits. In one implementation, the power distribution subsystem can include automated ground-bond verification circuitry that prevents the air-cooled heat generation module and the liquid-cooled heat generation module from energizing resistive heater element and variable-speed fans until the circuitry detects a satisfactory ground connection, and the supervisory controller can log completion of electrical safety checks for traceability. Alternatively, or additionally, the PDU/busbar can adapt input termination for facility voltages (e.g., 415 V or 480 V three-phase) and can support traditional PDU wiring and/or ORV3-style busbar architectures to accommodate different data-hall standards. Thus, the PDU/busbar together with the branch protection devices and the contactors and fast gating solve ramp-readiness and safety gating challenges by providing high-capacity, protected feeds with millisecond-class switching and modular isolation, which enables subsequent programmable load generation and dynamic emulation of time-varying AI rack power profiles.

### Connect Control Communications

An operator may connect field-bus wiring and/or Ethernet cabling to a control-network interface and may enable a wireless interface according to facility requirements, and the supervisory controller can execute connect control communications to establish a control communications link established with a remote workstation and/or a building management system. More specifically, the supervisory controller can configure network settings by assigning Internet Protocol addressing, applying authentication credentials, and programming firewall rules to secure bidirectional data exchange. In particular, the supervisory controller can negotiate and maintain protocol sessions using TCP/IP, Modbus, BACnet, and/or a proprietary industrial field-bus and can support polling and event-driven telemetry for real-time power, thermal, and hydraulic measurements. Additionally, the supervisory controller can expose digital commands, configuration parameters, and remote profile initiation services while the touchscreen HMI can present link status and can accept operator confirmation to enable external control. Further, the control communications link established can configure the supervisory controller, the touchscreen HMI, the sensor array, and the data logger to stream a real-time telemetry stream and to accept safety interlock signals from facility automation. Alternatively, the supervisory controller can repeat connect control communications after a network topology change to restore connectivity and can log all configuration changes to the data logger for traceability. Thus, the supervisory controller enables secure, low-latency coordination with external systems to support millisecond-class command updates, facility-coupled safety overrides, and remote orchestration, which addresses dynamic response and integration challenges of hybrid-cooled emulation at scale.

### Configure Liquid Path

Generally, the supervisory controller can execute configure liquid paths to allocate a portion of a total power demand setpoint to the liquid-cooled heat generation module and to command the fluid management subsystem to shape a hydraulic response that matches a hydraulic and airflow target set of an emulation parameter set. More specifically, the liquid-cooled heat generation module can energize liquid-cooled modules to convert per-module power setpoints into a heated coolant stream within an internal liquid loop and a liquid heat exchanger while the power distribution subsystem supplies electrical energy; in one implementation, the liquid-cooled heat generation module can ramp heater power to reproduce step, ramp, or pulse behaviors with millisecond-class transients. Additionally, the electronically controlled valve and/or the calibrated orifice set of the hydraulic impedance emulator can set hydraulic impedance to produce an adjusted coolant flow and a commanded differential pressure such that a pressure-drop versus flow characteristic presented at quick-disconnect couplings matches a user-defined target profile. In particular, the supervisory controller can validate liquid thermal conditions by using the sensor array to measure supply temperature, return temperature, volumetric flow rate, absolute pressure, differential pressure, and optional conductivity or glycol concentration, and the supervisory controller can adapt valve position and heater power in closed loop to maintain the commanded hydraulic and thermal conditions under varying facility coolant supply states. Also, the supervisory controller can coordinate configure liquid path with configure air path and execute dynamic emulation profile to support a user-selected hybrid split without duplicating airflow configuration details in this section. Thus, the supervisory controller and the fluid management subsystem address combined-cooling emulation, programmable split, controllable hydraulic impedance, and fast dynamic response by producing a liquid path configured state that enables accurate reproduction of coolant distribution unit behavior during high-density AI rack commissioning.

### Energize Liquid-Cooled Modules

Generally, the liquid-cooled heat generation module can energize an electric heater block according to an emulation parameter set by drawing commanded current through the power distribution subsystem to produce a heated coolant stream consistent with a hybrid split command and a dynamic power profile. More specifically, the power distribution subsystem can actuate contactors and fast gating to deliver a time-varying current waveform to the electric heater block over a range of rise times (e.g., from sub-millisecond to several seconds) to reproduce bursty or modulated loads. Also, the module sensors can monitor supply and return coolant temperatures, flow rates, and differential pressures and can provide a real-time telemetry stream to the supervisory controller for closed-loop regulation of per-module power setpoints. In particular, the liquid heat exchanger can transfer heat from the electric heater block into an internal liquid loop to generate a heated coolant stream while the hydraulic impedance emulator can coordinate an electronically controlled valve and a calibrated orifice set to maintain a specified pressure-drop versus flow characteristic. Additionally, the recirculation sub-loop can use a pump and a secondary heat exchanger to stabilize flow and thermal mass so that the liquid-cooled heat generation module tracks the emulation parameter set without overshoot. Then, the supervisory controller can schedule energization across multiple liquid-cooled heat generation module in parallel to satisfy per-module power setpoints and can allocate aggregate liquid-side power according to the updated hybrid split target. Furthermore, the hot-swappable module interface can support insertion or removal of a liquid-cooled heat generation module during operation to provide N+1 redundancy while the over-temperature/pressure protection and the leak detection system can assert a safety override signal to limit or terminate the electric heater block when protection thresholds are exceeded. Alternatively, the touchscreen HMI can accept user commands that cause the supervisory controller to ramp, pulse, or terminate the electric heater block so that the power distribution subsystem enforces the requested energization sequence. Thus, the liquid-cooled heat generation module and the coordinated subsystems address reproduction of time-varying AI rack profiles with millisecond-class dynamics, provide programmable split control on the liquid side while respecting hydraulic impedance constraints, and support scalable, redundant operation across multiple hot-swappable modules.

### Set Hydraulic Impedance

Generally, the supervisory controller can execute the set hydraulic impedance step by commanding the hydraulic impedance emulator to reproduce a target differential-pressure versus flow characteristic defined in an emulation parameter set. More specifically, the electronically controlled valve can modulate a valve position over a calibrated range to vary hydraulic resistance in the liquid manifold until the sensor array reports a measured differential pressure and a measured flow rate that align with a selected target curve (e.g., 50-200 liters per minute at approximately 1-3 bar differential pressure). In particular, the recirculation sub-loop can adjust a pump speed to coarsely position the operating point on the target curve while the electronically controlled valve can provide fine trimming to minimize steady-state and dynamic error. Additionally, the calibrated orifice set can introduce fixed impedance elements that the supervisory controller can switch into the liquid path to establish repeatable baseline pressure drops or to create piecewise-linear segments of a non-linear AP-flow profile. Then, the sensor array can sample upstream and downstream pressures and a volumetric flow rate at a high rate, and the supervisory controller can iteratively update valve commands and pump speed according to a closed-loop control algorithm that can include proportional-integral-derivative control and/or a model-predictive control variant to reduce the instantaneous deviation from the hydraulic and airflow target set. In one implementation, the touchscreen HMI can allow a user to select a library profile corresponding to a reference coolant distribution unit or a facility water system, and the supervisory controller can scale the profile to facility limits before applying the commands. In another implementation, multiple electronically controlled valve can coordinate to synthesize complex, non-linear impedance behavior, and the supervisory controller can schedule command updates at sub-10-millisecond intervals to follow time-varying setpoints such as steps, ramps, or periodic modulations. Therefore, the hydraulic impedance emulator and the supervisory controller can produce an adjusted coolant flow and a programmed hydraulic impedance configuration that address the absence of controllable hydraulic impedance in conventional load banks and enable accurate reproduction of facility AP-flow conditions for commissioning and performance validation.

### Validate Liquid Thermal Conditions

Generally, the supervisory controller can validate liquid thermal conditions by sampling a heated coolant stream, an adjusted coolant flow, and an emulation parameter set and by querying module sensors positioned at an inlet and an outlet of the liquid-cooled heat generation module for supply temperature, return temperature, and volumetric flow rate. More specifically, the sensor array can stream real-time measurements to the supervisory controller at a sampling interval (e.g., between 10 ms and 1 s), and the supervisory controller can compare the measurements against allowable ranges encoded in the emulation parameter set, such as absolute temperature limits (e.g., between 10 and 60° C.), differential temperature thresholds (e.g., between 2 and 20° C.), and flow boundaries (e.g., between 50 and 200 LPM). In particular, the supervisory controller can reduce or increase electrical power delivered to the liquid-cooled heat generation module by issuing per-module power setpoints to the heat generation assembly when a measured parameter departs from a corresponding allowable range. Additionally, the electronically controlled valve can modulate hydraulic impedance according to a commanded valve position to raise or lower the volumetric flow rate until the sensor array reports a return to a target region of the emulation parameter set. Then, the recirculation sub-loop can stabilise temperature or flow by activating a pump and, optionally, by rejecting excess heat through a secondary heat exchanger while the buffer reservoir can attenuate short-duration transients. Alternatively, the supervisory controller can execute the validation in a closed-loop mode that continuously adjusts setpoints or in an open-loop mode that executes checks at discrete intervals of a test profile. Also, the data logger can record all measured values and commanded adjustments with timestamps to produce a commissioning telemetry dataset for subsequent analysis or compliance reporting. Further, the over-temperature/pressure protection can apply protective limits to the supervisory controller by asserting a safety override signal when the real-time telemetry stream crosses a safety boundary. Thus, the supervisory controller can ensure that the liquid cooling subsystem operates within safe and representative conditions, which addresses the technical challenge of achieving accurate hybrid-cooled AI rack emulation under programmable hydraulic impedance and protects facility infrastructure from out-of-specification operation.

### Configure Air Path

The supervisory controller can configure air path by allocating a portion of a total power demand setpoint to an air-cooled heat generation module according to a hybrid split command and by computing the portion as a complement of power allocated to a liquid-cooled heat generation module. More specifically, the supervisory controller can energise air-cooled modules by commanding a resistive heater element to dissipate assigned electrical power and by sequencing energisation across multiple air-cooled heat generation module to achieve per-module power setpoints. In particular, the supervisory controller can set fan speeds by commanding variable-speed fans of an airflow management subsystem to achieve a target airflow rate and a target back-pressure within an air duct and plenum, where the supervisory controller can define each target as an absolute value or as a time-varying profile that includes steps, ramps, pulses, and/or frequency sweeps. Additionally, the supervisory controller can validate air thermal conditions by reading a sensor array at an air outlet of the air-cooled heat generation module and by comparing a measured outlet-air temperature to a reference temperature profile contained in an emulation parameter set. Then, the supervisory controller can adjust heater power and/or fan speed in real time to conform the heated airflow stream to the specified outlet temperature and the specified flow conditions and can coordinate the adjustment with configure liquid path to preserve the target hybrid split. Alternatively, the supervisory controller can modulate the air path in response to a real-time telemetry stream that reflects facility electrical power and/or facility coolant supply conditions so that the supervisory controller maintains a desired overall thermal emulation profile. In one implementation, the supervisory controller can execute millisecond-class dynamic modulation of the variable-speed fans and the resistive heater element, while in another implementation, a touchscreen HMI can accept coarse manual setpoints for airflow and power allocation. Thus, the supervisory controller addresses combined-cooling emulation by enabling a programmable 0-100% split between air and liquid heat rejection, addresses time-varying and bursty profiles by driving fan and heater commands with dynamic profiles, and addresses fast transient requirements by applying closed-loop, millisecond-scale adjustments that result in an air path configured state and configure the airflow management subsystem and the air-cooled heat generation module for active emulation.

### Execute Dynamic Emulation Profile

Generally, the supervisory controller can execute dynamic emulation profile by commanding the hybrid-cooled load bank and AI rack emulator to follow a pre-programmed or user-defined dynamic power profile that varies over time and by initiating active emulation state for subsequent control actions. More specifically, the supervisory controller can allocate hybrid split in real time to apportion instantaneous electrical load between the liquid-cooled heat generation module and the air-cooled heat generation module according to a continuously adjustable hybrid split command between approximately 0% and 100% liquid heat rejection. In particular, the supervisory controller can generate real-time power commands to drive per-module power setpoints that track step changes, ramps, burst pulses, pseudo-random binary sequences, and frequency sweeps between approximately 0.001 Hz and 10 Hz with edge times down to the millisecond range. Additionally, the electronically controlled valve and the calibrated orifice set can adjust hydraulic impedance while the variable-speed fans can regulate airflow so that the fluid management subsystem and the airflow management subsystem maintain a hydraulic and airflow target set during time-varying operation. Also, the data logger can monitor and log telemetry to capture delivered power, supply and return temperatures, differential and absolute pressures, flow rates, and humidity as a real-time telemetry stream at sub-second or millisecond-class resolution for generation of a commissioning telemetry dataset. Further, the supervisory controller can adapt profile to facility conditions by modifying emulation profile adjustment and updated hybrid split target based on the real-time telemetry stream and, in one variant, by applying a model-predictive control variant to compensate for facility temperature, flow, or pressure changes. Moreover, the over-temperature/pressure protection and the leak detection system can enforce safety limits by issuing a safety override signal that causes contactors and fast gating to shed load, de-energise affected modules, and transition the hybrid-cooled load bank and AI rack emulator toward a safe state. Thus, the supervisory controller and associated subsystems can reproduce bursty AI-rack transients with millisecond-class response, can program a 0-100% liquid-to-air split while maintaining controllable hydraulic impedance and airflow, and can sustain reliable operation under facility disturbances, which collectively address single-mode limitations, dynamic response gaps, programmable split constraints, and hydraulic emulation deficiencies of conventional load banks.

### Generate Real-time Power Commands

The supervisory controller can generate real-time power commands by synthesizing or replaying a dynamic power profile from an emulation parameter set and/or a pre-programmed workload trace, and the supervisory controller can additionally incorporate an emulation profile adjustment when the supervisory controller receives changing facility conditions. More specifically, the supervisory controller can issue high-frequency control signals to the liquid-cooled heat generation module and the air-cooled heat generation module at update rates sufficient to achieve millisecond-class edge transitions with edge times as short as 1 millisecond. In one implementation, the supervisory controller can apply step changes, ramps, burst pulses, pseudo-random binary sequences, and frequency sweeps with frequency content ranging from approximately 0.001 Hz to 10 Hz by commanding the electric heater block and the resistive heater element through contactors and fast gating of the power distribution subsystem. Additionally, the supervisory controller can interpolate intermediate set-points and generate a total power demand setpoint that conforms to a target hybrid split indicated by a hybrid split command while maintaining compatibility with electrical limits of the heat generation assembly. In narrower embodiments, the supervisory controller can synchronize the real-time power commands with a real-time telemetry stream produced by the data logger and with adaptive adjustments received as an emulation profile adjustment to maintain emulation fidelity during changing boundary conditions. Alternatively, the supervisory controller can derive the real-time power commands from closed-loop feedback by consuming a real-time telemetry stream that includes temperature, flow, and pressure measurements from the sensor array. Further, the supervisory controller can enforce slew-rate limits and current harmonics compliance by constraining commanded transitions and by coordinating gating states of the contactors and fast gating. Additionally, the over-temperature/pressure protection can issue a safety override signal that the supervisory controller can incorporate to inhibit or reduce commanded power according to electrical and facility codes. In one implementation, the supervisory controller can apportion provisional power between a liquid path handled by the liquid-cooled heat generation module and an air path handled by the air-cooled heat generation module to remain consistent with an updated hybrid split target while deferring per-module allocation to allocate hybrid split in real time. Therefore, the supervisory controller and the referenced subsystems can reproduce time-varying, bursty AI-rack power profiles with sub-Hertz modulation and millisecond edges, can apportion power across liquid and air paths over a 0-100% range, and can uphold electrical compliance and safety, thereby addressing limitations in dynamic response and combined-cooling emulation.

### Allocate Hybrid Split in Real Time

The supervisory controller can allocate hybrid split in real time by computing per-module power setpoints from a total power demand setpoint and an updated hybrid split target contained in an emulation parameter set, and the supervisory controller can stream the resulting per-module power setpoints to a liquid-cooled heat generation module and to an air-cooled heat generation module so that a sum of liquid and air heat rejection tracks a commanded dynamic power profile. More specifically, the sensor array can provide a real-time telemetry stream including electrical power, liquid flow rate, liquid supply and return temperature, liquid differential pressure, air temperature, and module operational status, and the supervisory controller can execute a closed-loop algorithm that continuously adjusts heater drive of an electric heater block and a resistive heater element while compensating for transient changes in coolant temperature, coolant flow, or coolant pressure. In particular, an electronically controlled valve can modulate hydraulic impedance to maintain a fraction of total heat on the liquid path, and variable-speed fans can modulate airflow to maintain a complementary fraction on the air path, while contactors and fast gating can step or ramp electrical drive stages according to step changes, ramps, and burst pulses of the dynamic power profile. Additionally, the hot-swappable module interface can declare module availability to the supervisory controller so that the supervisory controller can reallocate the hybrid split across remaining modules when a faulted module or an inserted module changes capacity, and the over-temperature/pressure protection can inject a safety override signal that the supervisory controller can honor by saturating or derating per-module power setpoints. Alternatively, in a model-predictive control variant, the supervisory controller can predict near-term facility and module states over an exemplary 50-500 ms horizon and can bias the updated hybrid split target to meet sub-Hertz modulation while preserving millisecond-class transient fidelity. In one implementation, the data logger can record all allocation decisions together with the real-time telemetry stream to form a commissioning telemetry dataset for subsequent validation of split adherence across an exemplary 0-100% liquid fraction range. Therefore, the supervisory controller and associated subsystems can maintain a continuously adjustable hybrid split under time-varying conditions and can reproduce bursty AI rack profiles with rapid response, which addresses combined-cooling control, split programmability, and dynamic response challenges of prior load banks.

### Monitor and Log Telemetry

The data logger can monitor and log telemetry by acquiring electrical parameters, hydraulic parameters, thermal parameters, mechanical parameters, and control system states from the sensor array while the supervisory controller executes the dynamic emulation profile. Generally, the data logger can sample and record power, voltage, and current relative to the total power demand setpoint and per-module power setpoints at a frequency of at least 1 Hz, with an optional increase to a sampling rate sufficient to capture millisecond-class transients required by the dynamic power profile. More specifically, the sensor array can measure liquid supply and return pressures, differential pressure across the hydraulic impedance emulator, and flow rate, and the sensor array can measure liquid supply and return temperatures together with air inlet and outlet temperatures. In particular, the airflow management subsystem can provide fan rotational speed feedback, and the hydraulic impedance emulator can provide valve position feedback, while the supervisory controller can provide fan speed commands and module enable or disable status. Additionally, the data logger can timestamp each record and can store data locally and/or can transmit a real-time telemetry stream to the supervisory controller and to a remote server for monitoring, analysis, and archival to a commissioning telemetry dataset. Then, the supervisory controller can consume the real-time telemetry stream to close a feedback loop that can adjust emulation parameters and/or can update an emulation profile adjustment in real time according to measured values. Alternatively, the touchscreen HMI can select a predefined or user-defined data acquisition profile that the data logger can execute to tailor sampling channels and rates, and the over-temperature/pressure protection can generate an alarm or can trigger a safe-state transition when a monitored parameter exceeds a predefined threshold. Thus, the data logger and the supervisory controller can provide synchronized, high-rate observability that enables verification of bursty transients, hybrid split control behavior, and facility interaction, which can address limitations in dynamic response and mixed-mode cooling validation encountered by conventional load banks.

### Enforce Safety Limits

Generally, the over-temperature/pressure protection can enforce safety limits by comparing a real-time telemetry stream against configurable thresholds that the supervisory controller can store for liquid flow rate (e.g., between 0.1 and 10.0 L/s), liquid supply and return temperature (e.g., between 5 and 60 degrees C.), liquid differential and absolute pressure (e.g., between 20 and 600 kPa), air temperature (e.g., between 10 and 80 degrees C.), electrical power (e.g., between 1 kW and 1 MW), and leak detection state. More specifically, the sensor array can sample parameters at rates (e.g., between 100 Hz and 10 kHz) and can stream measurements to the supervisory controller, and the supervisory controller can detect excursions according to time-weighted windows that the supervisory controller can tune to reduce nuisance trips during bursty transients. In particular, the supervisory controller can execute a staged response protocol that can initiate a controlled ramp-down by reducing per-module power setpoints (e.g., between 1 and 100 kW per module) and by commanding the variable-speed fans to follow a predefined ramp profile (e.g., between 5% and 50% per second) until parameters re-enter allowable bands. Additionally, the power distribution subsystem can actuate contactors and fast gating to disconnect branch protection devices for affected modules, and the power distribution subsystem can open a main contactor to isolate the entire hybrid-cooled load bank and AI rack emulator when the supervisory controller can classify a violation as severe. Also, the emergency stop can de-energize all heating elements and can disable power distribution when the supervisory controller can command an immediate shutdown or when an operator can press a physical actuator of the emergency stop. Then, the supervisory controller can generate a safety override signal that can clamp the total power demand setpoint and can override per-module power setpoints that the allocate hybrid split in real time can produce. Furthermore, the data logger can record the violating sensor, the threshold, the duration, and the action taken, and the touchscreen HMI can render visual and audible alarms while the touchscreen HMI can present operator prompts for acknowledgement and recovery. Alternatively, in a model-predictive control variant, the supervisory controller can forecast threshold crossings using recent gradients of the real-time telemetry stream and can preemptively reduce heater commands and can adjust the updated hybrid split target to avoid trips. In one implementation, a programmable logic controller of the supervisory controller can implement the safety logic in ladder or function-block code, and embedded firmware of the over-temperature/pressure protection can perform independent cutoff to satisfy applicable UL and/or IEC functions, and the supervisory controller can apply ASHRAE guideline limits for coolant and air temperatures. Additionally or alternatively, the supervisory controller can execute periodic self-tests by pulsing contactors and fast gating, by simulating sensor faults to verify over-temperature/pressure protection reactions, and by verifying continuity of the emergency stop circuit prior to and during operation. Thus, the over-temperature/pressure protection and the supervisory controller can maintain safe operation during millisecond-class transients and during megawatt-class loading, which enables accurate reproduction of bursty AI rack profiles while preventing damage and while supporting scalable, modular deployments.

### Adapt Profile to Facility Conditions

A supervisory controller can adapt profile to facility conditions by ingesting a real-time telemetry stream from a sensor array and by comparing the measured facility coolant supply temperature, coolant flow rate, and supply and/or return pressure against a hydraulic and airflow target set of an emulation parameter set. More specifically, the supervisory controller can detect a deviation that exceeds an exemplary error threshold (e.g., ±2% relative to a target thermal response or a target hydraulic response) and can compute an emulation profile adjustment and an updated hybrid split target that align a dynamic power profile with observed facility behavior. In particular, the supervisory controller can scale a total power demand setpoint, can alter a slew rate and a duration of steps, ramps, and pulses within the dynamic power profile, and can redistribute per-module power setpoints through allocate hybrid split in real time to maintain a commanded fraction of liquid-cooled and/or air-cooled heat rejection. Additionally, a hydraulic impedance emulator can adjust an electronically controlled valve and a calibrated orifice set to regulate pressure-drop versus flow characteristics, and variable-speed fans can adjust fan speeds to regulate airflow and air-side pressure targets. In one implementation, the supervisory controller can execute a closed-loop algorithm, such as proportional-integral-derivative control, model-predictive control, and/or rule-based logic, at a continuous update rate or at discrete intervals to generate the emulation profile adjustment while respecting a safety override signal. For example, in one example, the supervisory controller can compensate for a facility supply temperature increase by increasing commanded heater power of a liquid-cooled heat generation module and by raising fan speeds of an air-cooled heat generation module to preserve outlet temperature and pressure-drop trajectories. Then, the data logger can log the measured facility conditions and the corresponding emulation profile adjustment for post-test analysis and validation of emulation accuracy. Thus, the supervisory controller and cooperating subsystems can preserve accuracy of bursty, time-varying emulation while facility conditions drift, can sustain programmable split control across a 0-100% range, and can maintain dynamic response without violating hydraulic and airflow targets.

### Terminate and Safe Shutdown

Generally, the supervisory controller can terminate and safe shutdown by executing a controlled sequence that transitions the hybrid-cooled load bank and AI rack emulator from an active emulation state to a safe-shutdown state and to a load bank safely isolated configuration upon completion of a profile or upon an operator command via the touchscreen HMI and/or a remote control-network interface. More specifically, the power distribution subsystem can ramp down thermal load by reducing electrical power to the heat generation assembly according to per-module power setpoints over a defined interval to prevent abrupt transients in the facility electrical power. In particular, the liquid-cooled heat generation module can decrease heater output of the electric heater block while the air-cooled heat generation module can decrease heater output of the resistive heater element until both outputs approach zero. Additionally, the fluid management subsystem can maintain coolant circulation by operating the pump and the recirculation sub-loop, while the airflow management subsystem can maintain forced convection by operating the fan array and the variable-speed fans to remove residual heat. Then, the sensor array can monitor temperatures of the liquid heat exchanger, the internal liquid loop, the air duct housing, and the liquid manifold, and the supervisory controller can compare the real-time telemetry stream against a configurable safe threshold (e.g., below 50° C.) to determine completion of the cool-down interval. Subsequently, the electronically controlled valve can cool-down and isolate the liquid path by closing flow to the hydraulic impedance emulator and the liquid manifold, and the pressure relief and drain assembly can relieve residual pressure to prevent unintended flow and/or leaks. Alternatively, the quick-disconnect couplings can maintain sealing during isolation while the variable-speed fans can taper airflow to idle once the cooled and isolated state is verified. Additionally or alternatively, the over-temperature/pressure protection can enforce safety limits by issuing a safety override signal, and the contactors and fast gating can immediately de-energize the PDU/busbar if the leak detection system or the sensor array detects an abnormal condition. Also, the data logger can archive data and report results by consolidating the telemetry dataset from the ramp down thermal load and the cool-down and isolate phases into an archived telemetry package, and the supervisory controller can generate a commissioning report with a pass/fail status based on predefined acceptance criteria. Furthermore, the touchscreen HMI can present the commissioning report to an operator and can store the archived telemetry package in non-volatile memory for later retrieval and correlation with the commissioning telemetry dataset. In one implementation, the supervisory controller can adapt the terminate and safe shutdown sequence in real time based on the real-time telemetry stream to extend fan runtime or coolant circulation until the cooled and isolated state is achieved. Thus, the terminate and safe shutdown procedure addresses dynamic-response and safety challenges by shaping end-of-test transients, by preventing thermal shock to liquid-cooled and air-cooled modules, and by providing verifiable isolation and complete data capture for reproducible high-density commissioning workflows.

### Ramp Down Thermal Load

Generally, the supervisory controller can execute the ramp down thermal load step by generating a decay profile and commanding the per-module power setpoints to reduce electrical input of the liquid-cooled heat generation module and the air-cooled heat generation module according to a time-dependent schedule. More specifically, the supervisory controller can implement a linear, exponential, or user-specified function to constrain a maximum temperature gradient (e.g., between 0.5 and 10 degrees Celsius per minute) and a minimum ramp duration (e.g., between 30 seconds and 30 minutes) while targeting an end-state power or temperature. In particular, the liquid-cooled heat generation module can decrease heater duty of the electric heater block and can transfer residual heat through the liquid heat exchanger while the fluid management subsystem can regulate flow using the hydraulic impedance emulator to hold a programmed pressure-drop versus flow trajectory during cooldown. Additionally, the electronically controlled valve can modulate valve position and the calibrated orifice set can provide a bounded hydraulic conductance so that the adjusted coolant flow tracks a commanded decay without inducing thermal shock. Also, the air-cooled heat generation module can reduce power of the resistive heater element while the variable-speed fans can taper airflow according to a coordinated schedule that preserves component temperature margins and avoids abrupt acoustic or pressure transients. Then, the power distribution subsystem can sequence contactors and fast gating to step down feeder segments in stages consistent with the per-module power setpoints so that branch protection devices do not experience nuisance trips. Alternatively, the supervisory controller can trigger the ramp down thermal load step automatically upon completion of the execute dynamic emulation profile, upon reception of a safety override signal generated by the over-temperature/pressure protection, or upon a user command entered through the touchscreen HMI. Further, the data logger can monitor and log telemetry by sampling temperatures, pressures, flows, voltages, and currents to generate a telemetry dataset for post-test analysis of facility cooling response during the ramp-down interval. Additionally or alternatively, the supervisory controller can adapt the decay profile in real time by processing the real-time telemetry stream and updating the per-module power setpoints and the updated hybrid split target to emulate realistic shutdown behavior of high-density IT infrastructure. Thus, the coordinated ramp down thermal load step addresses dynamic response and hybrid-path control by shaping heat rejection in both liquid and air paths while preventing thermal-mechanical stress and by producing telemetry that validates combined-cooling shutdown performance.

### Cool-Down and Isolate

Generally, the supervisory controller can execute the cool-down and isolate step by maintaining operation of cooling auxiliaries after the ramped-down thermal state occurs, and the supervisory controller can continue the variable-speed fans and, if present, the pump of the recirculation sub-loop to remove residual heat from the heat generation assembly. More specifically, the sensor array can sample temperatures at designated locations of the liquid-cooled heat generation module and the air-cooled heat generation module, such as a liquid return of the liquid manifold, a surface of a liquid heat exchanger, and an air exhaust of the air duct housing, at a sampling rate (e.g., 1-10 Hz) while the supervisory controller can compare the sampled temperatures against a target threshold (e.g., between 30° C. and 50° C., such as 40° C.). In particular, the electronically controlled valve of the hydraulic impedance emulator can close the liquid supply and return paths when the supervisory controller confirms that all monitored temperatures fall below the target threshold for a configured dwell time (e.g., 10-120 s), thereby hydraulically isolating internal modules from a facility coolant supply. Additionally, the supervisory controller can de-energize the variable-speed fans, the pump, and auxiliary devices of the airflow management subsystem and the fluid management subsystem after hydraulic isolation completes, and the supervisory controller can transition the configuration to a cooled and isolated state. Alternatively, the touchscreen HMI can accept an operator command to initiate or bypass portions of the cool-down and isolate step, and the supervisory controller can enforce safety limits by preventing premature isolation when any monitored temperature exceeds the target threshold. Then, the data logger can record a telemetry dataset that includes a cool-down duration, final temperature values by sensor location, and a state-transition timestamp for compliance or maintenance records. Thus, the supervisory controller and the cooling auxiliaries address the safe serviceability challenge of hybrid liquid-and-air load emulation by ensuring controlled thermal decay, by enabling hydraulic isolation without exposing external coolant distribution units to heat soak, and by facilitating hot-swappable module handling in megawatt-class deployments without sacrificing dynamic emulation capabilities established in earlier steps.

### Archive Data and Report Results

The supervisory controller can execute archive data and report results by ingesting a telemetry dataset from the data logger and by packaging the telemetry dataset together with run metadata into an archived telemetry package for persistent retention. More specifically, the data logger can store time-stamped measurements of electrical power consumption, liquid and air temperature, liquid flow rate, differential and absolute pressure, fan speed, valve position, and alarm or fault events to non-volatile local memory and/or can transmit the same measurements to a remote server for offboard storage. In particular, the supervisory controller can automatically generate a commissioning report that details measured thermal, hydraulic, and electrical performance metrics of the hybrid-cooled load bank and AI rack emulator during an emulation cycle, can render graphical representations of time-varying power profiles, hybrid split ratios, pressure-drop versus flow curves, and response times to commanded transients, and can export the commissioning report in machine-readable formats such as CSV and JSON and in human-readable formats such as PDF with optional formatting for compliance with industry standards such as ASHRAE TC9.9. Additionally, the control and monitoring subsystem can archive raw and processed data to a secure, access-controlled repository and can transmit automated notifications or summaries to designated facility personnel, and the touchscreen HMI can support manual or scheduled report generation at the conclusion of an emulation cycle or periodically during long-duration tests. Thus, the supervisory controller and the data logger can address validation of time-varying, bursty power behavior, programmable hybrid split over a 0-100% range, and controllable hydraulic impedance by preserving synchronized evidence of combined thermal-airflow-hydraulic responses, which can enable repeatable comparison against facility targets and can document compliance for megawatt-class, modular deployments.

### Definitions

“Hybrid split” means the ratio of heat rejected to the liquid path versus the air path, adjustable from approximately 0-100%.

“Dynamic profile” means a time-varying command of power, flow, or temperature comprising steps, ramps, pulses, PRBS, or frequency sweeps between ˜0.001-10 Hz and transient edges down to milliseconds.

“Hydraulic emulation” means imparting a specified pressure-drop versus flow characteristic to the liquid path via controllable valves, orifices, and piping geometry.

We claim:

1. A hybrid-cooled load bank and AI rack emulator comprising:
a structural frame;
at least one liquid-cooled heat generation module comprising an electric heater block thermally coupled to a liquid heat exchanger and an internal liquid loop;
at least one air-cooled heat generation module comprising a resistive heater element and variable-speed fans within an air duct housing;
a fluid management subsystem comprising a liquid manifold and a hydraulic impedance emulator configured to present a pressure-drop (AP) versus flow characteristic within a range of about 50 to 200 liters per minute at about 1 to 3 bar differential pressure;
an airflow management subsystem comprising a controllable fan array;
a power distribution subsystem comprising branch protection devices and contactors configured to deliver millisecond-class switching;
a supervisory controller configured to (i) execute dynamic power profile having edge times less than or equal to about one millisecond, and (ii) allocate power between the liquid-cooled heat generation module and the air-cooled heat generation module according to a continuously adjustable 0 to 100 percent hybrid split; and
a sensor array configured to provide real-time electrical, thermal, and hydraulic telemetry to the supervisory controller.

2. The hybrid-cooled load bank and AI rack emulator of claim 1, further comprising a top panel with liquid couplings carrying quick-disconnect couplings mounted on an upper surface and configured for blind-mate connection of facility coolant supply and return lines.

3. The hybrid-cooled load bank and AI rack emulator of claim 1, wherein the hydraulic impedance emulator comprises:
at least one electronically controlled proportional valve; and
a calibrated orifice set selectable to provide discrete flow-restriction values.

4. The hybrid-cooled load bank and AI rack emulator of claim 1, further comprising a recirculation sub-loop comprising a variable-speed pump, a secondary heat exchanger, and a buffer reservoir configured to add programmable thermal mass.

5. The hybrid-cooled load bank and AI rack emulator of claim 1, wherein the power distribution subsystem comprises solid-state fast-gating devices configured to reproduce bursty power waveforms between about 0.001 Hz and about 10 Hz.

6. The hybrid-cooled load bank and AI rack emulator of claim 1, wherein each of the liquid-cooled heat generation module and the air-cooled heat generation module mates to the structural frame through a hot-swappable module interface that provides blind-mate electrical, fluid, and signal connections enabling N+1 redundancy.

7. The hybrid-cooled load bank and AI rack emulator of claim 1, further comprising a data logger configured to store a commissioning telemetry dataset derived from the sensor array at a millisecond sampling resolution.

8. The hybrid-cooled load bank and AI rack emulator of claim 1, wherein a safety and service subsystem comprises an emergency stop switch, leak-detection sensors, and over-temperature/pressure protection interlocked with the supervisory controller.

9. The hybrid-cooled load bank and AI rack emulator of claim 1, further comprising a mobility interface comprising a plurality of swivel casters and a set of leveling feet configured to allow roll-in deployment and rigid positioning.

10. A method of emulating a hybrid-cooled AI rack using the apparatus of claim 1, comprising:
establishing physical connections to facility electrical power by connecting to a power distribution subsystem of the apparatus and to facility coolant by coupling quick-disconnect couplings to supply and return lines;
selecting, via a supervisory controller or a touchscreen HMI of the apparatus, a hybrid split value between 0 percent and 100 percent liquid heat rejection and loading a dynamic power profile;
energizing the liquid-cooled heat generation module and setting hydraulic impedance with electronically controlled valve to match a target pressure-drop versus flow curve;
energizing the air-cooled heat generation module and setting fan speeds to achieve a target airflow and back-pressure;
executing the dynamic power profile while the supervisory controller allocates the hybrid split in real time and logs telemetry from a sensor array;
enforcing safety limits based on sensor feedback;
performing a controlled ramp-down followed by cool-down and hydraulic isolation of a coolant circuit; and
archiving telemetry and generating a commissioning report.

11. The method of claim 10, wherein the supervisory controller employs a model-predictive control routine that forecasts system states 1 to 5 seconds ahead to minimize deviation from target power, hybrid split, and hydraulic profiles.

12. The method of claim 10, further comprising adapting the dynamic power profile in real time to compensate for changes in facility supply temperature, flow, or pressure.

13. The method of claim 10, wherein the dynamic power profile comprises pseudo-random binary sequences and frequency sweeps from about 0.001 Hz to about 10 Hz with edge times less than or equal to about one millisecond.

14. The method of claim 10, further comprising sweeping the hybrid split across a full 0 to 100 percent range to characterize facility cooling performance.

15. The method of claim 10, wherein the controlled ramp-down limits temperature gradients to a predefined maximum and is followed by closure of electronically controlled valve to hydraulically isolate the apparatus.

16. The method of claim 10, wherein archiving telemetry comprises generating an archived telemetry package that is compressed and encrypted for secure long-term retention and audit.

17. The method of claim 10, wherein setting hydraulic impedance comprises selecting an orifice plate from the calibrated orifice set and modulating the proportional valve to follow a time-varying pressure-drop versus flow schedule.

18. The method of claim 10, further comprising hot-swapping a heat generation module via a hot-swappable module interface during an active emulation state while maintaining N+1 capacity and continuous telemetry logging.

19. The hybrid-cooled load bank and AI rack emulator of claim 1, further comprising a top panel with liquid couplings, wherein the top panel positions a set of quick-disconnect couplings above electrical sections to mitigate leak risk and enables overhead facility hose routing.

20. The hybrid-cooled load bank and AI rack emulator of claim 1, further comprising a front-mounted touchscreen HMI configured to provide local control, status display, and emergency override of dynamic power profile.
